(19) United States
(12) Patent Application Publication
(10) Pub. No.: US 2012/0268146 A1
(43) Pub. Date: Oct. 25, 2012

(54) VOLTAGE DETECTOR

(75) Inventor: Masaru Nagao, Yatomi-shi (JP)

(73) Assignee: Toyota Jidosha Kabushiki Kaisha, Toyota-shi (JP)

(21) Appl. No.: 13/257,777

(22) PCT Filed: Jan. 15, 2010
(86) PCT No.: PCT/JP2010/050410

§ 371 Date: Sep. 20, 2011

(51) Int. Cl. G01R 27/26

(52) U.S. Cl. 324/686

(57) ABSTRACT

A voltage detector includes a radiator plate which is connected to the collector of an IGBT, a detection lead frame which forms a capacitor along with the radiator plate, and a collector voltage detection circuit which detects the collector voltage of the IGBT on the basis of the amount of changes in electric charges accumulated in the capacitor. With this voltage detector, the collector voltage of the IGBT can be detected without causing an increase in the size of the system even under a high-voltage condition.

### TECHNICAL FIELD

The present invention relates to a voltage detector that detects a terminal voltage of a power semiconductor device.

### BACKGROUND ART

In the related art, as a system using a power semiconductor device, for example, a semiconductor power converter described in Patent Literature 1 is known. The semiconductor power converter has an insulated gate bipolar transistor (hereinafter, referred to as IGBT) which serves as a power semiconductor device, a voltage-division resistor which divides the collector voltage of the IGBT, and a capacitor which is connected in parallel to the voltage-division resistor.

### CITATION LIST

### Patent Literature

[Patent Literature 1] Japanese Unexamined Patent Application Publication No. 2002-44934

### SUMMARY OF INVENTION

### Technical Problem

In the above-described semiconductor power converter of the related art, the collector voltage of the IGBT can be detected by using the voltage-division resistor and the capacitor which is connected in parallel to the voltage-division resistor. In recent years, there has been a demand for using the semiconductor power converter under a high-voltage condition of about DC 600 to 900 V.

On the other hand, in order to use the above-described semiconductor power converter of the related art under a high-voltage condition, it is necessary that the voltage-division resistor for dividing the collector voltage has high wattage, or multiple resistors are connected in series. Besides, the system inevitably increases in size.

Accordingly, the invention has been made in order to solve the above-described problem, and an object of the invention is to provide a voltage detector capable of detecting the terminal voltage of a power semiconductor device without causing an increase in the size of the system even under a high-voltage condition.

### Solution to Problem

The invention provides a voltage detector for detecting a voltage between a first terminal and a second terminal of a power semiconductor device. The voltage detector includes an electrode plate which is connected to the first terminal of the power semiconductor device, a detection electrode which is arranged in the vicinity of the electrode plate so as to form a first capacitor along with the electrode plate, and a voltage detection circuit which detects a voltage between the first terminal and the second terminal of the power semiconductor device on the basis of changes in electric charges accumulated in the first capacitor.

In the voltage detector, the detection electrode is arranged in the vicinity of the electrode plate connected to the first terminal of the power semiconductor device such that the first capacitor is formed between the electrode plate and the detection electrode. The voltage (hereinafter, referred to as a terminal voltage) between the first terminal and the second terminal of the power semiconductor device is detected on the basis of changes in the electric charges accumulated in the first capacitor. For this reason, the terminal voltage can be detected without providing a resistor for dividing the terminal voltage. Therefore, it is possible to avoid an increase in the size of the system even under a high-voltage condition.

The voltage detection circuit may have an operational amplifier which has an inverting input terminal connected to the first capacitor and a non-inverting input terminal connected to a predetermined voltage source, and a second capacitor which is connected between the inverting input terminal and an output terminal of the operational amplifier. In this case, the amount of changes in the electric charges accumulated in the first capacitor is moved to the second capacitor which is connected between the inverting input terminal and the output terminal of the operational amplifier. As a result, changes in the electric charges accumulated in the first capacitor are reflected in the output voltage of the operational amplifier, such that the terminal voltage of the power semiconductor device can be detected on the basis of the output voltage of the operational amplifier.

The voltage detection circuit may have a third capacitor which is connected to the first capacitor, a diode which branches off between the first capacitor and the third capacitor, and is connected in parallel to the third capacitor, and a fourth capacitor which is connected in series to the cathode of the diode on the downstream side of the diode. In this case, when the terminal voltage rises, the third capacitor and the fourth capacitor are in parallel, and the terminal voltage is divided by the first capacitor, the third capacitor, and the fourth capacitor. When the terminal voltage falls, the electric charges of the fourth capacitor are maintained by the diode provided on the upstream side of the fourth capacitor. Therefore, when the terminal voltage falls, the terminal voltage is divided by the first capacitor and the third capacitor, such that the voltage-division ratio of the first capacitor is reduced compared to when the terminal voltage rises. As a result, changes in the terminal voltage can be accurately detected.

### Advantageous Effects of Invention

According to the invention, it is possible to provide a voltage detector capable of detecting the terminal voltage of a power semiconductor device without causing an increase in the size of the system even at a high voltage.

### BRIEF DESCRIPTION OF DRAWINGS

FIG. 1 is a diagram showing the configuration of a power module according to this embodiment.

FIG. 2 is a diagram showing the circuit configuration of a voltage detector.

FIG. 3 is a diagram showing the circuit configuration of a voltage detector.

FIG. 4 is a timing chart showing an operation of the voltage detector shown in FIG. 3.

### DESCRIPTION OF EMBODIMENTS

Hereinafter, embodiments of the invention will be described in detail with reference to the accompanying drawings. In the description of the drawings, the same constituent elements are represented by the same reference numerals, and overlapping description will be omitted.

### First Embodiment

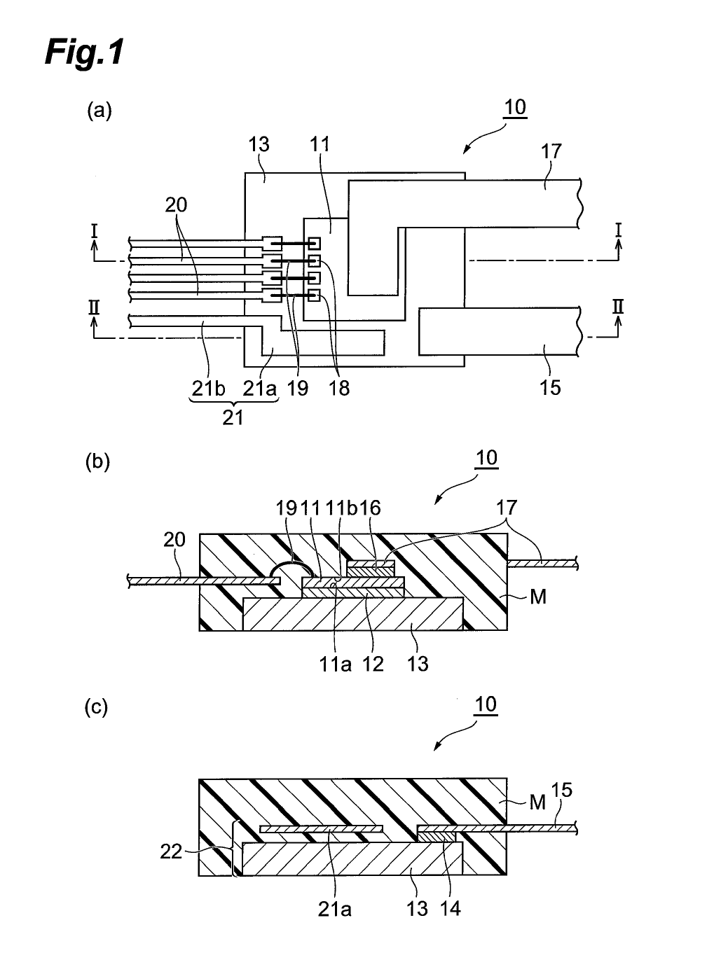

FIG. 1 is a diagram showing the configuration of a power module using a voltage detector according to this embodiment. FIG. 1(a) is a schematic plan view of the power module. FIG. 1(b) is a schematic sectional view taken along the line I-I of FIG. 1(a). FIG. 1(c) is a schematic sectional view taken along the line II-II of FIG. 1(a). In FIG. 1(a), mold resin M shown in FIGS. 1(b) and (c) is not shown.

A power module 10 includes an IGBT 11 serving as a power semiconductor device. The IGBT 11 has a collector (first terminal) which is formed by at least a part of a rear surface 11a. To the rear surface 11a of the IGBT 11, a radiator plate (electrode plate) 13 is attached by a soldering 12. The radiator plate 13 is formed of a conductive material and is electrically connected to the collector of the IGBT 11 through the soldering 12.

To the radiator plate 13, a power line lead frame 15 is attached by a soldering 14. Thus, the power line lead frame 15 is electrically connected to the collector of the IGBT 11 through the soldering 14, the radiator plate 13, and the soldering 12. The power line lead frame 15 is formed in a wide flat plate shape as a voltage-withstanding layout against a high DC voltage.

The IGBT 11 has an emitter (second terminal) which is formed by at least a part of an upper surface 11b. To the upper surface 11b of the IGBT 11, a power line lead frame 17 is attached by a soldering 16. The power line lead frame 17 is electrically connected to the emitter of the IGBT 11 through the solder 16. The power line lead frame 17 is formed in a wide flat plate shape as a voltage-withstanding layout against a high DC voltage.

In the upper surface 11b of the IGBT 11, a plurality of gate connection regions 18 (in this case, four gate connection regions) are formed to input a control signal to the gate of the IGBT 11. Each gate connection region 18 is connected to a control signal line lead frame 20 through a wire 19. Thus, each control signal line lead frame 20 is electrically connected to the gate of the IGBT 11 through the wire 19 and the gate connection region 18.

As described above, the power module 10 can apply a voltage between the collector and the emitter of the IGBT 11 by using the power line lead frames 15 and 17 and can also control the gate potential of the IGBT 11 by using the control signal line lead frames 20 to turn on/off the IGBT 11. A plurality of power modules 10 can be combined to form an inverter circuit, and can be used as a semiconductor power converter. The power module 10 includes mold resin M which is formed so as to cover the IGBT 11, the radiator plate 13, and the like.

The power module 10 further includes a detection lead frame 21. The detection lead frame 21 is constituted by an electrode portion (detection electrode) 21a and a connection portion 21b. The electrode portion 21a substantially has a rectangular flat plate shape and is arranged in the vicinity of the radiator plate 13. Thus, the electrode portion 21a and the radiator plate 13 form a parallel flat-plate capacitor (first capacitor) 22 connected to the collector of the IGBT 11. The capacitor 22 accumulates the amount of electric charges according to a voltage (hereinafter, referred to as a collector voltage) which is applied between the collector and emitter of the IGBT 11. The mold resin M is arranged between the radiator plate 13 and the electrode portion 21a of the detection lead frame 21.

The connection portion 21b of the detection lead frame 21 extends from one end of the electrode portion 21a and is formed as a single body with the electrode portion 21a. The connection portion 21b is used to connect the capacitor 22 to a collector voltage detection circuit described below. The radiator plate 13, the detection lead frame 21, and the collector voltage detection circuit constitute a voltage detector for detecting the collector voltage of the IGBT 11.

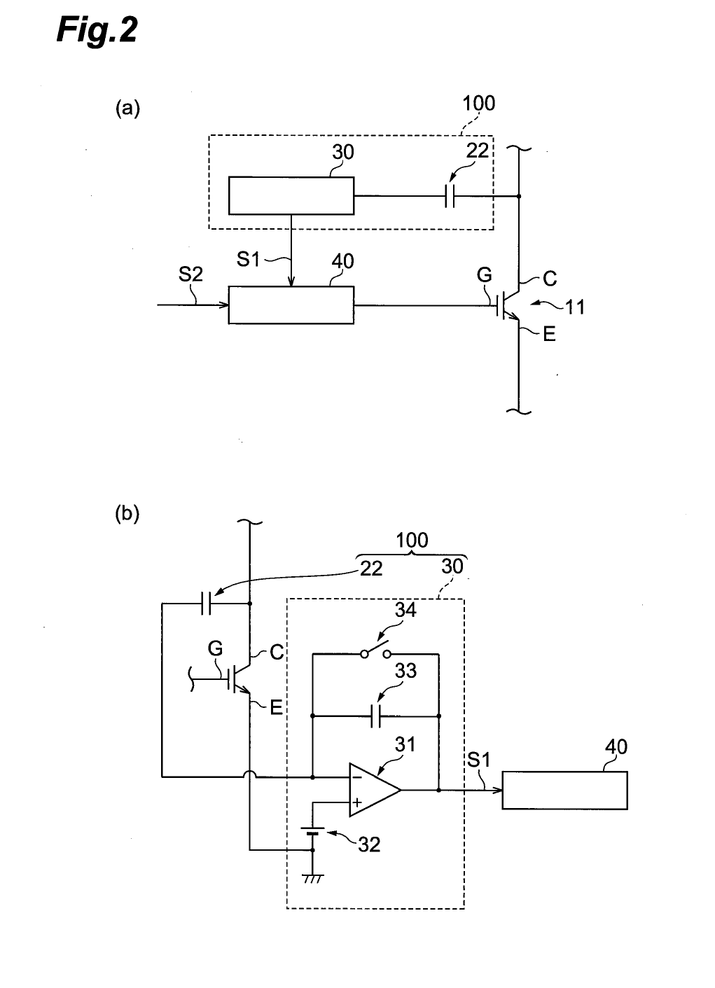

FIG. 2 is a diagram schematically showing the circuit configuration of a voltage detector according to this embodiment. As shown in FIG. 2(a), a voltage detector 100 includes the capacitor 22 (the radiator plate 13 and the electrode portion 21a of the detection lead frame 21) and a collector voltage detection circuit 30. The collector voltage detection circuit 30 is connected to the capacitor 22. The collector voltage detection circuit 30 is a circuit for detecting the collector voltage of the IGBT 11 on the basis of changes in the electric charges accumulated in the capacitor 22. The collector voltage detection circuit 30 outputs a detection voltage signal S1 representing the detection result of the collector voltage of the IGBT 11 to a gate driving/control circuit 40 described below.

The gate driving/control circuit 40 is connected to the gate G of the IGBT 11. The gate driving/control circuit 40 receives the detection voltage signal S1 from the collector voltage detection circuit 30 and also receives a control signal S2 for controlling the gate potential of the IGBT 11 from the outside. The gate driving/control circuit 40 controls the gate potential of the IGBT 11 to turn on/off the IGBT 11 on the basis of the detection voltage signal S1 and the control signal S2.

Subsequently, the details of the collector voltage detection circuit 30 will be described. FIG. 2(b) is a circuit diagram showing the configuration of the collector voltage detection circuit 30. As shown in FIG. 2(b), the collector voltage detection circuit 30 has an operational amplifier 31, a voltage source 32, a capacitor (second capacitor) 33, and a switch 34. The operational amplifier 31 has an inverting input terminal connected to the capacitor 22 and a non-inverting input terminal connected to the voltage source 32. The capacitor 33 is connected between the inverting input terminal and the output terminal of the operational amplifier 31. The switch 34 is connected in parallel to the capacitor 33. The emitter E of the IGBT 11 is grounded along with the voltage source 32.

Next, the actions and effects of the voltage detector 100 will be described. Before the IGBT 11 is turned on/off, the switch 34 is temporarily turned on. Thus, the electric charges accumulated in the capacitor 33 are temporarily reset. Then, the switch 34 is turned off. At this time, a voltage on the side of the capacitor 22 which is not connected to the collector C is fixed (virtually grounded) at a voltage Vref of the voltage source 32 by the action of the operational amplifier 31. For this reason, if the IGBT 11 is subsequently turned on or off and the collector voltage of the IGBT 11 is changed, the electric charges accumulated in the capacitor 22 are changed. The amount of changes in the electric charges is moved to the capacitor 33 and reflected in the output voltage of the operational amplifier 31. Therefore, with the voltage detector 100, the collector voltage of the IGBT 11 can be detected on the basis of the output voltage of the operational amplifier 31.

### Second Embodiment

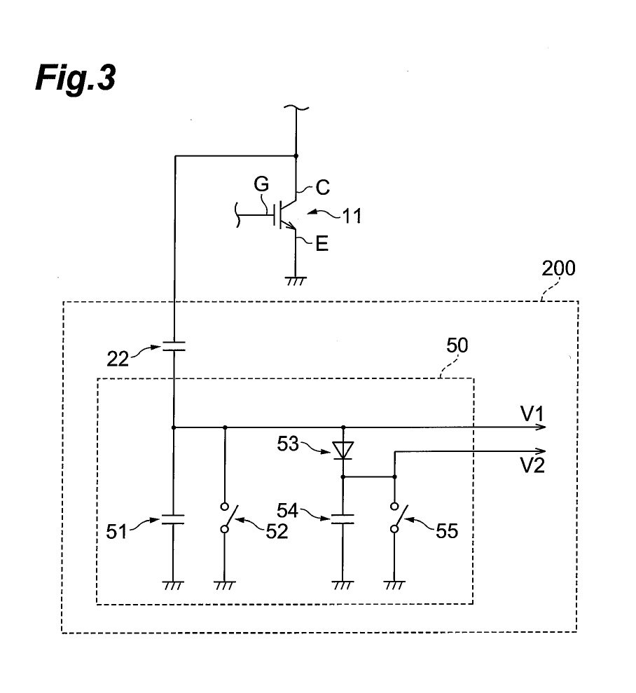

Subsequently, a second embodiment of a voltage detector will be described with reference to FIG. 3. Similarly to the voltage detector 100 of the first embodiment, the voltage detector is applied to the power module 10. As shown in FIG. 3, a voltage detector 200 includes the capacitor 22 (the radiator plate 13 and the electrode portion 21a of the detection lead frame 21) and a collector voltage detection circuit 50. Similarly to the collector voltage detection circuit 30, the collector voltage detection circuit 50 is a circuit for detecting the collector voltage of the IGBT 11 on the basis of changes in electric charges accumulated in the capacitor 22.

The collector voltage detection circuit 50 has a capacitor (third capacitor) 51, a switch 52, a diode 53, a capacitor (fourth capacitor) 54, and a switch 55.

The capacitor 51 is connected between the capacitor 22 and the ground. The diode 53 branches off between the capacitor 22 and the capacitor 51, and is connected in parallel to the capacitor 51. The capacitor 54 is connected in series to the cathode of the diode 53 on the downstream side of the diode 53. The switch 52 branches off between the capacitor 22 and the capacitor 51, and is connected in parallel to the capacitor 51. The switch 55 branches off between the diode 53 and the capacitor 54, and is connected in parallel to the capacitor 54.

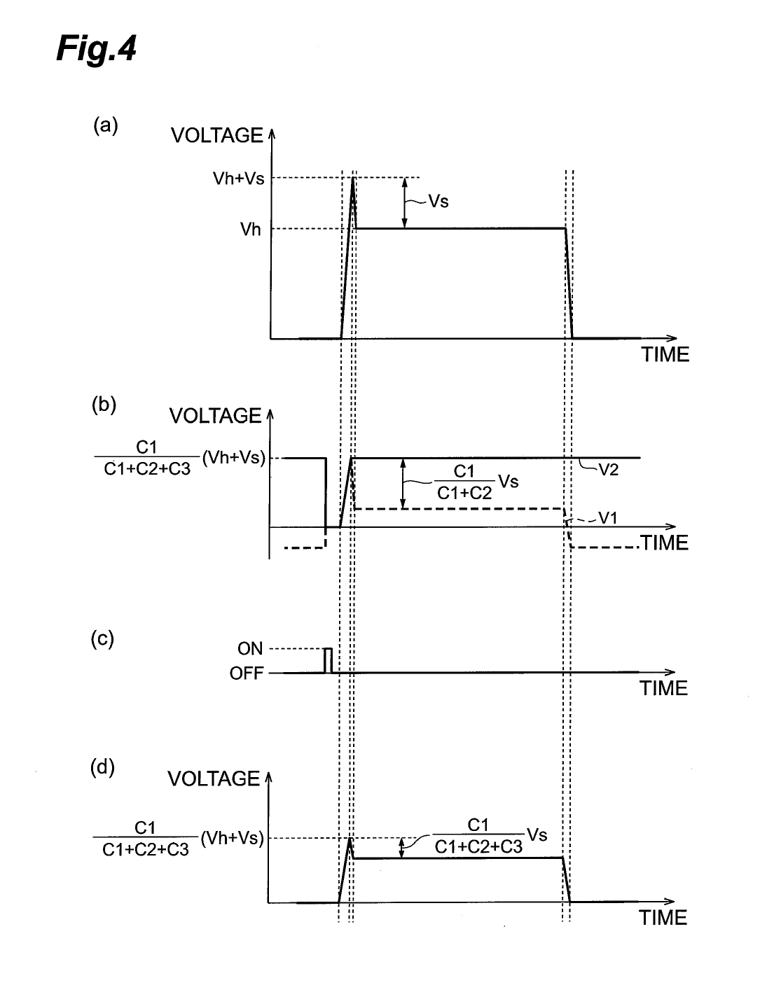

Next, the actions and effects of the voltage detector 200 will be described. In the following description, reference is made to FIG. 4 in addition to FIG. 3. FIG. 4 is a timing chart showing changes in a voltage according to switching of the switch 52, switch 55. FIG. 4(a) shows a collector voltage. In FIG. 4(b), a broken line indicates a voltage-division point voltage V1, and a solid line indicates a voltage-division point voltage V2. FIG. 4(c) shows a timing for switching the IGBT 11. FIG. 4(d) shows a voltage-division point voltage in a voltage detector of a comparative example. The voltage detector of the comparative example is different from the voltage detector 200 in that the switches 52 and 55 and the diode 53 are not provided.

First, the switches 52 and 54 are manipulated in order of OFF, ON, and OFF. Thus, the electric charges accumulated in the capacitors 51 and 54 are reset. Thereafter, if the IGBT 11 is turned off, the collector voltage rises. At this time, if a system voltage is Vh and a serge voltage is Vs, the collector voltage rises to Vh+Vs.

As the collector voltage rises to Vh+Vs, the voltage-division point voltage V1 rises to C1·(Vh+Vs)/(C1+C2+C3). Here, C1, C2, and C3 are respectively the capacitance values of the capacitor 22, the capacitor 51, and the capacitor 54. The voltage effect by the diode 53 is not taken into consideration.

Thereafter, the collector voltage is lowered to the system voltage Vh and stabilized. As the collector voltage is lowered, the voltage-division point voltage V1 is also changed (lowered). The change amount ΔV1 of the voltage-division point voltage V1 becomes −C1·Vs/(C1+C2) because the electric charges of the capacitor 54 are maintained by the effect of the diode 53.

The voltage detector of the comparative example shown in FIG. 4(d) does not include the diode 53. Thus, in the comparative example, the change amount of the voltage-division point voltage becomes −C1·Vs/(C1+C2+C3).

As described above, with the voltage detector 200 of this embodiment, when the collector voltage rises, the capacitor 51 and the capacitor 54 are in parallel, and the collector voltage is divided by the capacitor 22, the capacitor 51, and the capacitor 54. When the collector voltage falls, the electric charges of the capacitor 54 are maintained by the diode 53 provided on the upstream side of the capacitor 54. Thus, when the collector voltage falls, the collector voltage is divided by the capacitor 22 and the capacitor 51, such that the voltage-division ratio of the capacitor 22 is reduced compared to when the collector voltage rises. For this reason, the change amount ΔV1 of the voltage-division point voltage V1 increases compared to the voltage detector of the comparative example in which the diode 53 is not provided. As a result, C1, C2, and C3 are set to appropriate values, such that the changes in the voltage-division point voltage V1 can fall within a desired range, and the serge voltage Vs can be significantly detected as the changes in the voltage-division point voltage V1. Therefore, the changes (the serge voltage Vs) in the collector voltage can be accurately detected.

As described above, with the voltage detector 100 of the first embodiment and the voltage detector 200 of the second embodiment, the collector voltage of the IGBT 11 can be detected on the basis of changes in the electric charges accumulated in the capacitor 22. For this reason, the collector voltage can be detected without providing a resistor for dividing the collector voltage. Therefore, it is possible to avoid an increase in the size of the system under a high-voltage condition.

The voltage detector 100 of the first embodiment and the voltage detector 200 of the second embodiment use the capacitor 22 which is formed by using the radiator plate 13 of the power module 10, thus it is not necessary to separately provide a capacitor for detecting the collector voltage.

Although in the foregoing embodiments, a case has been described where an IGBT is used as a power semiconductor device, the invention is not limited thereto. For example, a power MOSFET (Metal Oxide Semiconductor Field Effect Transistor) may be used.

### INDUSTRIAL APPLICABILITY

It is possible to provide a voltage detector capable of detecting the terminal voltage of a power semiconductor device without causing an increase in the size of the system even under a high-voltage condition.

### REFERENCE SIGNS LIST

11: IGBT, 13: radiator plate, 21: detection lead frame, 21a: electrode portion, 22, 33, 51, 54: capacitor, 30, 50: collector voltage detection circuit, 31: operational amplifier, 32: voltage source, 53: diode, 100, 200: voltage detector.

1. A voltage detector for detecting a voltage between a first terminal and a second terminal of a power semiconductor device, the voltage detector comprising:
an electrode plate which is connected to the first terminal of the power semiconductor device;
a detection electrode which is arranged in the vicinity of the electrode plate so as to form a first capacitor along with the electrode plate; and
a voltage detection circuit which detects a voltage between the first terminal and the second terminal of the power semiconductor device on the basis of changes in electric charges accumulated in the first capacitor.

2. The voltage detector according to claim 1,
wherein the voltage detection circuit has
an operational amplifier which has an inverting input terminal connected to the first capacitor and a non-inverting input terminal connected to a predetermined voltage source, and
a second capacitor which is connected between the inverting input terminal and the output terminal of the operational amplifier.

3. The voltage detector according to claim 1,
wherein the voltage detection circuit has
a third capacitor which is connected to the first capacitor,
a diode which branches off between the first capacitor and the third capacitor, and is connected in parallel to the third capacitor, and
a fourth capacitor which is connected in series to the cathode of the diode on the downstream side of the diode.
